(19) United States
(12) Patent Application Publication
(10) Pub. No.: US 2014/0352149 A1
(43) Pub. Date: Dec. 4, 2014

(54) Heat Exchanger for Electronic Assemblies

(71) Applicant: Transistor Devices, Inc. d/b/a TDI Power, Hackettstown, NJ (US)

(72) Inventors: John Santini, Columbia, NJ (US); Ronald Tallman, Dingmans Ferry, PA (US); Gary Mulcahy, Flanders, NJ (US)

(21) Appl. No.: 14/329,068

(22) Filed: Jul. 11, 2014

Related U.S. Application Data
(62) Division of application No. 13/240,504, filed on Sep. 22, 2011.
(60) Provisional application No. 61/419,930, filed on Dec. 6, 2010.

(51) Int. Cl. H05K 7/20; B21D 53/02

(52) U.S. Cl. CPC H05K 7/20218; B21D 53/02
USPC 29/890.03

(57) ABSTRACT

A liquid-cooled heat exchanger for electronic assemblies and a method of making the heat exchanger. The exchanger has a solid metal body in the form of an elongated flat plate to which the electronic assembly can be mounted, or a number of such plates formed in an L- or U-shaped configuration to enclose two or more sides of the assembly. The elongated body is formed by extrusion, with parallel enclosed longitudinal passages formed along a length of the body during the extrusion process. Transverse passages are drilled to intersect the extruded longitudinal passages. The longitudinal passages and transverse passages are plugged on at least one of their outside ends, and optionally at points along their lengths, to create desired patterns of liquid flow through the heat exchanger.

### REFERENCE TO RELATED APPLICATIONS

This application claims one or more inventions which were disclosed in Provisional Application No. 61/419,930, filed Dec. 6, 2010. The benefit under 35 USC §119(e) of the United States provisional application is hereby claimed, and the aforementioned application is hereby incorporated herein by reference.

### BACKGROUND OF THE INVENTION

1. Field of the Invention

The invention pertains to the field of heat exchangers. More particularly, the invention pertains to liquid-cooled heat exchangers and methods of manufacture thereof.

2. Description of Related Art

Electronic circuits must frequently operate in demanding physical environments in which liquid cooling is a preferred method for managing the heat associated with power losses. Conventional heat exchange systems use a monolithic air-to-liquid or surface-to-liquid heat exchangers to accomplish the cooling tasks. These conventional heat exchange systems have proven to be less than optimal when considering the aspects of cost and thermal management.

In many instances, it has become impossible to effectively couple all of the heat being generated in the system to the liquid cooling utilized to provide heat exchange, which results in excessive temperatures within the liquid-cooled structures. In addition, it is generally difficult to scale a particular solution either up or down in power, thereby requiring a ground up effort to support different power requirements.

Modern electronic equipment is often designed for mounting in racks or cabinets with only a small clearance between modules. This does not leave much room for large heat sinks or piping which might extend outward from the modules.

Heat exchangers for such modular assemblies are often in the form of flat plates which form one or more sides of the module case, to which circuit boards or heat-generating components may be mounted. If the heat exchangers are liquid cooled, the cooling liquid passes through pipes or tubes soldered or otherwise bonded to a surface of the plates or inset into a surface of the plate, with the fluid being supplied and exhausted from the exchangers through connections on an end of the plate. U.S. Pat. Nos. 5,829,516 or 6,333,849 show such an arrangement of tubes mounted to or inset into flat plates.

Liquid cooled heat exchanger plates have also been provided with internal cooling chambers through which liquid is circulated. U.S. Pat. No. 5,159,529 is an example of such an exchanger, in which essentially the entire interior of the plate forms a fluid chamber.

It is known to provide drilled holes through solid plates for cooling. U.S. Pat. No. 5,829,516, noted above, also, in prior art FIGS. 3-5, shows a heat exchange plate in which four parallel holes are drilled from one end through most of the length of a solid plate. Two cross-holes are drilled at least part-way through from the sides near the opposite end to cross-connect the two outer pairs of longitudinal holes. The ends of the cross-holes are plugged, and an external pipe is provided to interconnect the drilled end of the two inner holes, to provide a single serpentine path for the fluid.

White Paper TWO055, “Next Generation Military Vehicle Power Conversion Modules”, published in March 2008 by TDI Power (Transistor Devices, Inc.), shows, in FIGS. 9 and 10, a U-shaped water-cooled heat exchanger housing a power converter.

Holes are drilled the length of the three sides of the “U” for coolant circulation, similar to the arrangement in the U.S. Pat. No. 5,829,516 patent discussed above. While this arrangement has advantages in providing liquid cooling, drilling these long holes for coolant has proven problematic in manufacture.

U.S. Pat. No. 7,624,791 shows, in FIGS. 2A and 2B, a tubular cooling body having a central passageway, formed by using a hollow, drawn or extruded raw material. The body is then bent into a U-shaped configuration.

### SUMMARY OF THE INVENTION

The invention presents a liquid-cooled heat exchanger for electronic assemblies and a method of making the heat exchanger. The exchanger has a solid metal body in the form of an elongated flat plate to which an electronic assembly can be mounted, or a number of such plates formed in an L- or U-shaped configuration to enclose two or more sides of the assembly. The elongated body is formed by extrusion, with parallel enclosed longitudinal passages formed along a length of the body during the extrusion process. Transverse passages are drilled to intersect the extruded longitudinal passages. The longitudinal passages and transverse passages are plugged on at least one of their outside ends, and optionally at points along their lengths, to create desired patterns of liquid flow through the heat exchanger.

### BRIEF DESCRIPTION OF THE DRAWING

FIG. 1 shows a perspective view of an electronic assembly mounted within a U-shaped heat exchanger.

FIG. 2 shows a top view of a plate-type heat exchanger.

FIG. 3 shows a cut-through view of the heat exchanger of FIG. 2, along the lines 3-3.

FIG. 4 shows a perspective view of an L-shaped heat exchanger.

FIG. 5 shows a cut-through view of the heat exchanger of FIG. 4, along the lines 5-5.

FIG. 6 shows a perspective view of a U-shaped heat exchanger.

FIG. 7 shows a cut-through view of the heat exchanger of FIG. 6, along the lines 7-7.

FIGS. 8a-8c show sectional views of a plate-type heat exchanger, showing differing patterns of liquid flow.

FIG. 9 is a flowchart of a method of making a heat exchanger.

FIG. 10 shows examples of plugs for use with the heat exchanger.

### DETAILED DESCRIPTION OF THE INVENTION

The invention presents a liquid-cooled heat exchanger for electronic assemblies and a method of making the heat exchanger. The exchanger has a solid metal body in the form of an elongated flat plate to which the electronic assembly can be mounted, or a number of such plates formed in an L- or U-shaped configuration to enclose two or more sides of the assembly. The elongated body is formed by extrusion, with parallel enclosed longitudinal passages formed along a length of the body during the extrusion process. Cross-passages are drilled to intersect the extruded longitudinal passages. The longitudinal passages and cross-passages are plugged on at least one of their outside ends, and optionally at points along their lengths, to create desired patterns of liquid flow through the heat exchanger.

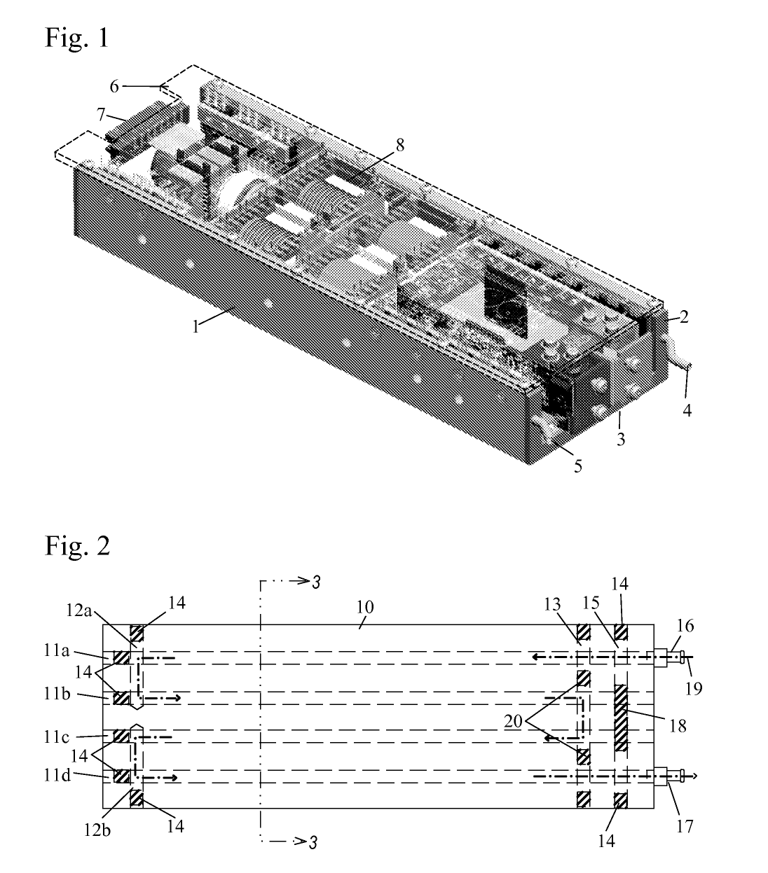

FIG. 1 shows a perspective view of an electronic assembly 8. The electrical components of the assembly, in this case a power supply, are conventionally mounted on a printed circuit board 6 which has a connector 7 allowing the assembly to connect to wiring or a bus in a rack or other mounting arrangement (not shown).

The assembly 8 is mounted within a U-shaped heat exchanger formed of a base plate 1 and sides 2 and 3, which closely surround the components and to which the circuit board 6 is mounted. Heat generated by the components is removed by liquid circulating in passages through the plate 1 and the sides 2 and 3, as will be described in greater detail below. Appropriate pipes or connectors 4 and 5 are provided to connect to a circulating supply of cooling liquid and to carry away heated liquid, as is conventional in a liquid-cooled apparatus.

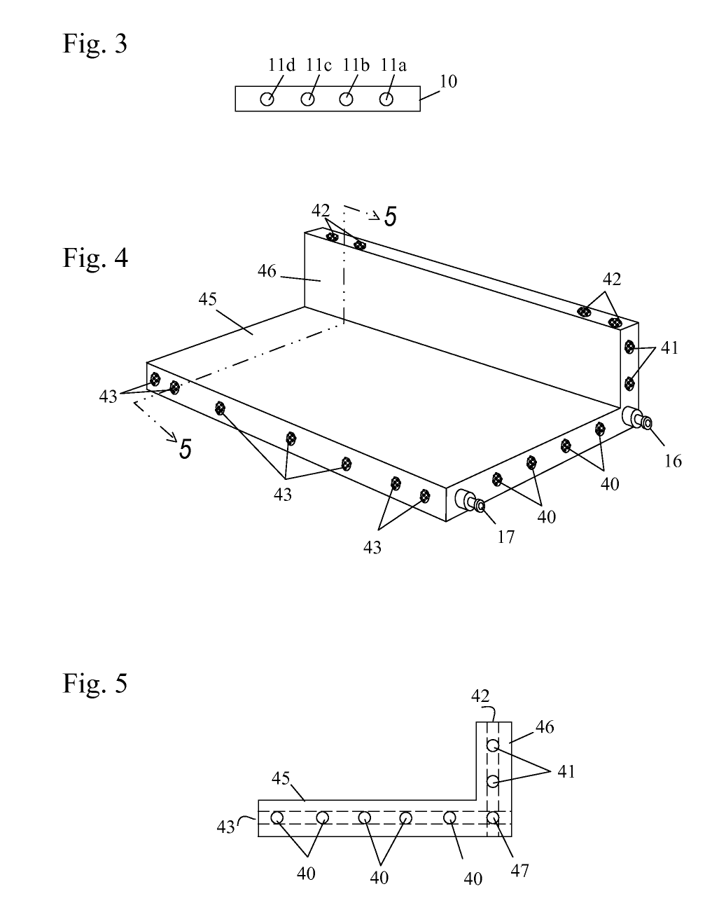

Looking at the heat exchanger in greater detail, FIG. 2 shows a top view of an embodiment of the invention in the form of a flat plate-type heat exchanger, and FIG. 3 shows a cut-through view of the heat exchanger of FIG. 2, along the lines 3-3.

The heat exchanger in this embodiment is a flat plate 10 made of a heat-conductive material such as aluminum or other metal, having a thickness, width and length. The dimensions of the plate 10 would be determined in a manner known to the art, so as to fit the electronic assembly which it is intended to cool and to fit in whatever mounting arrangement might be required.

The plate 10 is formed by extrusion, and in the process of extrusion a number of parallel passages are formed running longitudinally through the plate. In the example shown in FIG. 2, four such passages are shown—11a, 11b, 11c and 11d—but it will be understood that any number of passages could be included within the teachings of the invention. FIG. 2 shows a simple arrangement of evenly spaced longitudinal passages 11a-d, but it will be understood that the passages could be arranged to have more liquid coolant through parts of the plate where more heat load is expected, or, conversely, to avoid areas where holes might need to be drilled to mount larger components. Liquid inlet 16 and outlet 17 connectors provide connections to the circulating cooling liquid system (not shown).

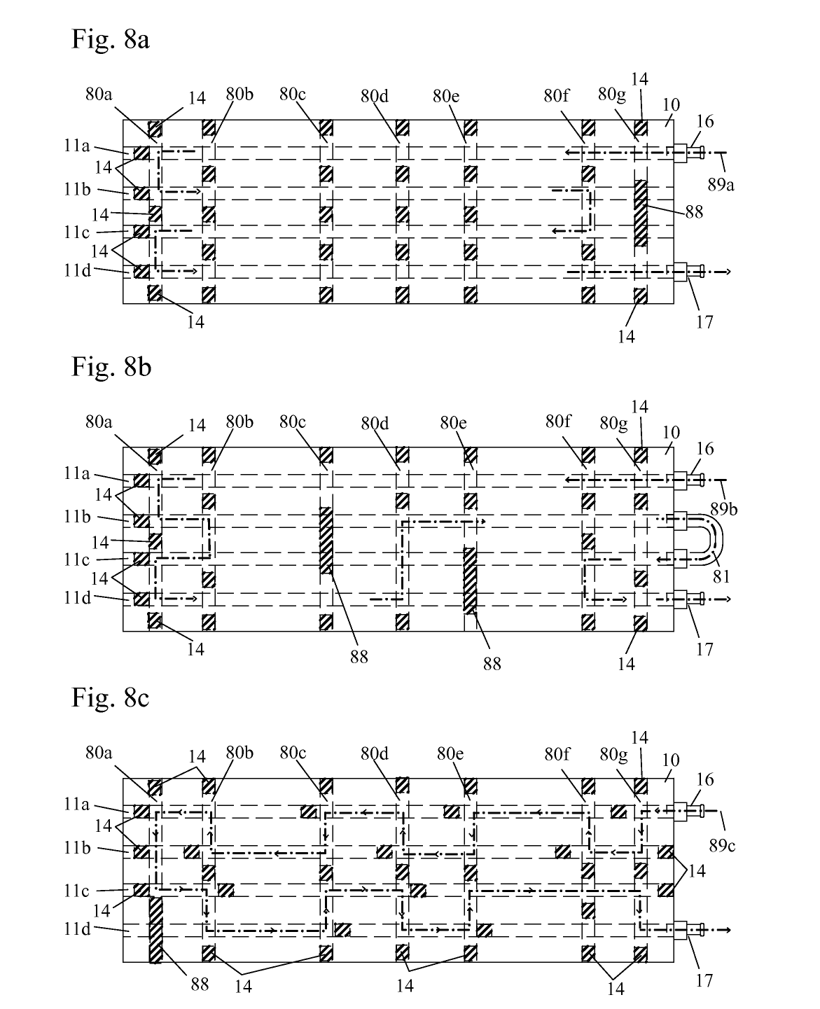

Transverse passages are drilled across the width of the plate 10, intersecting some or all of the longitudinal passages 11a-d. In the example of FIG. 2, parallel transverse passages 13 and 15 are drilled completely across the width of the plate 10, on the end of the plate 10 having connectors 16 and 17, intersecting all four longitudinal passages 11a-11d. On the other hand, transverse passages 12a and 12b, on the opposite end of the plate 10, are only drilled part-way across the width of the plate, so that transverse passage 12a only intersects longitudinal passages 11a and 11b, while transverse passage 12b intersects longitudinal passages 11c and 11d. As with the longitudinal passages, it will be understood that the particular arrangement of transverse passages shown in the figure are for example only. More or fewer transverse passages could be drilled, in different locations and arrangements, within the teachings of the invention. Transverse passages can be drilled to provide additional passages in areas needing additional cooling, or to avoid areas where mounting holes are needed. FIGS. 8a-8c, discussed below, show a plate with four longitudinal passages and seven transverse passages, for example.

It will be appreciated that, at the least, the outside ends of the transverse and longitudinal passages will need to be plugged to prevent the cooling liquid from the fluid input 16 from simply flowing out of the ends of the passages. This can be done by welding or brazing, or by inserting plugs 14 into the outer ends of the passages as shown in the figure.

FIG. 10 shows several examples of plugs as might be used within the teachings of the invention. Plugs 100 and 110, of differing lengths as will be discussed in greater detail below, could be made of resilient material and compressed into the passages, or the plugs 14 could be made of rigid material and press-fit into the passages and secured by a sealant or adhesive. Alternatively, the passages may be threaded along at least the outermost portion of their lengths, to facilitate screwing plug 120 into the plate.

The arrangement of intersecting longitudinal and transverse passages makes it possible to use additional plugs to create a desired internal liquid flow. Plugs can be relatively short and pushed into the transverse or longitudinal passages until they lodge between passages, thus blocking flow from one passage to another parallel to it. In the example of FIG. 2, this has been done in transverse passage 13, where plugs 20 block liquid flow through transverse passage 13 from longitudinal passage 11a to longitudinal passage 11b, or from 11c to 11d. Because there is no plug between longitudinal passages 11b and 11c, liquid can flow from one passage to the other through transverse passage 13.

Longer plugs can be used to block two or more longitudinal and transverse passages simultaneously, such as plug 18, shown pushed into transverse passage 15 across longitudinal passages 11b and 11c. This not only blocks flow along transverse passage 15, but also prevents flow between the intersecting longitudinal passages 11b and 11c.

Dash-dot line 19 shows the flow of fluid through the heat exchanger shown in FIG. 2. Fluid flows in connector 16, then along longitudinal passage 11a and through transverse passage 12a to longitudinal passage 11b. Plug 18 blocks passage 11b, so the fluid flows across transverse passage 13 to longitudinal passage 11c, then to transverse passage 12b, and back on longitudinal passage 11d to exit at connector 17.

FIG. 4 shows a perspective view of an L-shaped heat exchanger, and FIG. 5 shows a cut-through view of the heat exchanger of FIG. 4, along the lines 5-5.

An L-shaped heat exchanger would have a base plate 45 and side plate 46, preferably formed as a single unit by extrusion. Parallel longitudinal passages 40 and 47 are formed during the extrusion process along the length of the base plate 45, and a number of parallel transverse passages 43 are drilled across the plate to intersect the longitudinal passages 40. Similarly, parallel longitudinal passages 41 are formed in side plate 46, and transverse passages 42 are drilled to intersect the longitudinal passages 41 and also longitudinal passage 47 in the base plate 45. By having longitudinal passage 47 intersected by both sets of transverse passages 42 and 43, it is possible by appropriate insertion of plugs to direct fluid flow between connectors 16 and 17 through both base plate 45 and side plate 46.

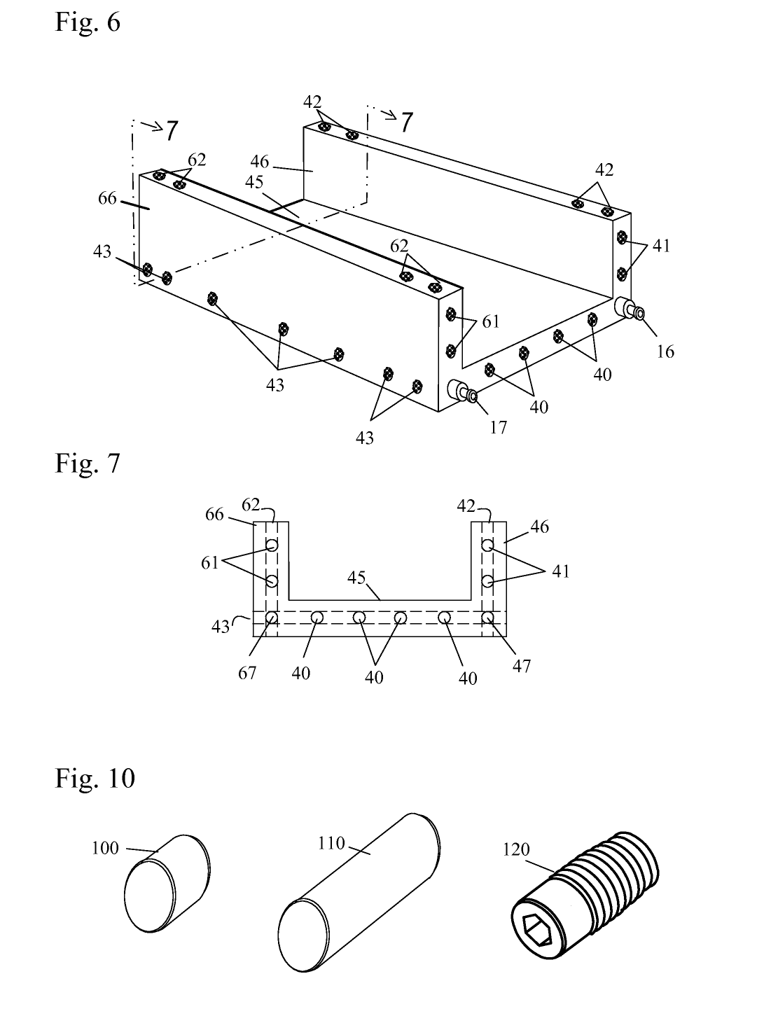

FIG. 6 shows a perspective view of a U-shaped heat exchanger, and FIG. 7 shows a cut-through view of the heat exchanger of FIG. 6, along the lines 7-7. An electronic assembly can be mounted to the U-shaped heat exchanger, as shown in FIG. 1, forming a modular liquid cooled electronic component.

As with the L-shaped heat exchanger described above, the U-shaped heat exchanger would have a base plate 45 and side plate 46, and would also have a second side plate 66. Preferably, all three plates 45, 46 and 67 are formed as a single unit by extrusion. Parallel longitudinal passages 40, 47 and 62 are formed during the extrusion process along the length of the base plate 45, and a number of parallel transverse passages 43 are drilled across the plate to intersect the longitudinal passages 40. Similarly, parallel longitudinal passages 41 are formed in side plate 46, and transverse passages 42 are drilled to intersect the longitudinal passages 41 and also longitudinal passage 47 in the base plate 45. Also, parallel longitudinal passages 61 are formed in side plate 66, and transverse passages 62 are drilled to intersect the longitudinal passages 61 and also longitudinal passage 67 in the base plate 45. By having longitudinal passages 47 and 67 intersected by all of the of transverse passages 42, 62 and 43, it is possible by appropriate insertion of plugs to direct fluid flow between connectors 16 and 17 through base plate 45 and both side plates 46 and 66.

Other designs of heat exchangers are possible within the teachings of the invention, in addition to the plate, L- and U-shaped exchangers described in detail above. For example, if the side walls 46 and 66 from the U-shaped exchanger were put on opposite surfaces of the plate 45, a Z-shaped heat exchanger could be produced. Alternatively, a full tube heat exchanger could be made by adding another plate parallel to plate 45, closing off the open side of the “U”. More or fewer passages could be provided than is shown in the examples, and either longitudinal or transverse passages could be omitted entirely on one side wall 46 or 66 as might be required for a particular application.

The use of the intersecting transverse and longitudinal passages and long and short plugs allows for flexibility and efficiency, by allowing a designer to use a standardized heat exchanger and then customize the fluid flow as required by the electronic components to be cooled. To illustrate this process, FIGS. 8a-8c show sectional views of a plate-type heat exchanger similar to that of FIG. 2, showing differing patterns of liquid flow created by different arrangements of plugs.

The heat exchanger of FIGS. 8a-8c has four longitudinal passages 11a-11d, formed as part of the extrusion process of making the plate 10. Seven transverse passages 80a-80g are drilled to intersect the longitudinal passages 11a-11d. It will be understood that the specific number and location of these passages are shown for explanatory purposes only, and the number and location of longitudinal and transverse passages can be varied within the teachings of the invention.

FIG. 8a shows a heat exchanger configured for a relatively simple fluid flow, similar to that of FIG. 2. As in FIG. 2, plugs 14 are placed at the ends of longitudinal passages 11a-11d opposite the end with connectors 16 and 17. Plugs 14 are also placed to block the ends of all of the transverse passages 80a-80g. Plugs 14 are also placed in transverse passage 80a between longitudinal passages 11b and 11c, and in transverse passages 80b-80f between longitudinal passages 11a and 11b, between longitudinal passages 11b and 11c, and between longitudinal passages 11c and 11d. A long plug 88 is placed in transverse passage 80g, blocking longitudinal passages 11b and 11c.

This results in a simple back-and-forth fluid flow shown by dot-dashed line 89a. Fluid flows in connector 16, then along longitudinal passage 11a and through transverse passage 80a to longitudinal passage 11b. Plug 88 blocks passage 11b, so the fluid flows across transverse passage 80f to longitudinal passage 11c, then to transverse passage 80a, and back on longitudinal passage 11d to exit at connector 17.

FIG. 8b shows a heat exchanger configured for a more circuitous flow, shown by dot-dashed line 89b. In this example, a U-shaped external fluid connector 81 is used at the end of the plate 10 which has connectors 16 and 17, to route fluid between longitudinal passages 11b and 11c. It will be understood that such external connectors could be used within the teachings of the invention to route fluid flow between other passages, as might be required for a particular flow pattern.

In the example of FIG. 8b, plugs 14 are placed at the ends of longitudinal passages 11a-11d opposite the end with connectors 16 and 17. Plugs are placed in the transverse passages 80a-80g as follows:
in transverse passage 80a, a plug 14 at each end and between longitudinal passages 11b and 11c.
in transverse passage 80b, a plug 14 at each end, between longitudinal passages 11a and 11b and between longitudinal passages 11c and 11d.
in transverse passage 80c, a plug 14 at each end, and a long plug 88 is placed across longitudinal passages 11c and 11d.
in transverse passage 80d, a plug 14 is placed at each end and between longitudinal passages 11a and 11b.
in transverse passage 80e, plugs 14 are placed at the end of the passage adjacent longitudinal passage 11a, and between longitudinal passages 11a and 11b, and a long plug 88 is placed across longitudinal passages 11c and 11d.
in transverse passage 80f, plugs 14 are placed at each end, between longitudinal passages 11a and 11b and between longitudinal passages 11b and 11c.
in transverse passage 80g, a plug 14 at each end, between longitudinal passages 11a and 11b and between longitudinal passages 11c and 11d.

This arrangement of plugs 14 and long plugs 88 results in a flow 89b from inlet connector 16 down the length of longitudinal passage 11a, through transverse passage 80a to longitudinal passage 11b, across transverse passage 80b to longitudinal passage 11c, across transverse passage 80a to longitudinal passage 11d. Fluid passes along 11d to transverse passage 80d, crosses over along 80d to longitudinal passage 11b. The fluid then exits the plate 10 through connector 81, and back into the plate 10 through longitudinal passage 11c, across transverse passage 80f to longitudinal passage 11d, then out through outlet connector 17.

FIG. 8c illustrates still another example of fluid flow 89c from connector 16 to connector 17, the flow being more complex than in FIG. 8a or 8b, as might be required by a particular electronic assembly.

In the example of FIG. 8c, plugs are placed in the transverse passages 80a-80g as follows:
in transverse passage 80a, a plug 14 at the end of the passage adjacent longitudinal passage 11a, and a long plug 88 is inserted from the opposite end, blocking longitudinal passage 11d.
in transverse passages 80b, 80c, 80d and 80e, a plug 14 at each end and between longitudinal passages 11b and 11c.
in transverse passage 80f, a plug 14 at each end and between longitudinal passages 11b and 11c and between longitudinal passages 11c and 11d.
in transverse passage 80g, a plug 14 at each end and between longitudinal passages 11b and 11c.

Plugs 14 are placed in longitudinal passages 11a-11d as follows:
in longitudinal passage 11a, at the end opposite connector 16, between transverse passages 80b and 80c, between transverse passages 80d and 80e, and between transverse passages 80f and 80g.
in longitudinal passage 11b, at both ends, between transverse passages 80a and 80b, between transverse passages 80c and 80d, and between transverse passages 80e and 80f.
in longitudinal passage 11c, at both ends, between transverse passages 80b and 80c, and between transverse passages 80d and 80e.
in longitudinal passage 11d, between transverse passages 80c and 80d, and between transverse passages 80e and 80f.

This arrangement of plugs 14 and long plugs 88 results in a flow 89c from inlet connector 16 into longitudinal passage 11a, through transverse passage 80g to longitudinal passage 11b, across transverse passage 80f to longitudinal passage 11a, across transverse passage 80e to longitudinal passage 11b. Fluid passes along 11b to transverse passage 80d, crosses over along transverse passage 80d to longitudinal passage 11a, back to longitudinal passage 11b through transverse passage 80c, then back to longitudinal passage 11a through transverse passage 80b. From longitudinal passage 11a, the flow crosses transverse passage 80a to longitudinal passage 11c, then up 11c to transverse passage 80b, across 80b to longitudinal passage 11d. From longitudinal passage 11d, flow crosses transverse passage 80c to longitudinal passage 11c, then back to longitudinal passage 11d on transverse passage 80d, back to longitudinal passage 11c on transverse passage 80e. The flow continues on longitudinal passage 11c to transverse passage 80g, where it crosses to longitudinal passage 11d, then out through outlet connector 17.

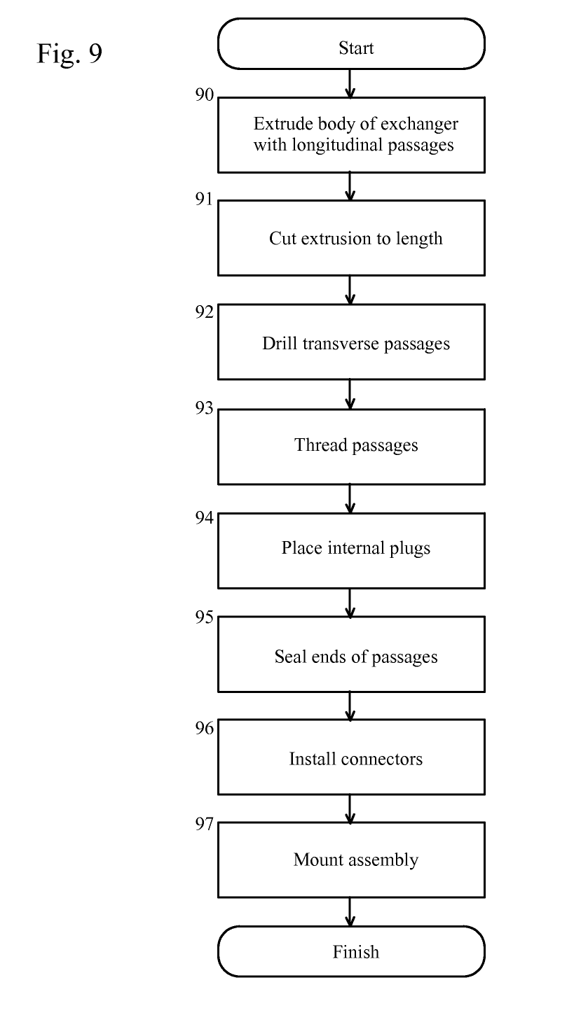

FIG. 9 is a flowchart of a method of making a heat exchanger of the kind described above. It will be understood that the method is applicable to the plate, L- and U-shaped exchangers.
90. First, the body of the heat exchanger is produced by extrusion. By methods known to the art, the body shape and dimensions can be determined as required. The longitudinal passages are formed as part of the extrusion process.
91. Optionally, the extrusion can be made much longer than the actual device, in which case the extrusion will be cut to length. Alternatively, the extrusion can be made to the desired length, and a cutting step will not be necessary.
92. The transverse passages are drilled.
93. If desired, all or some of the lengths of the longitudinal passages and transverse passages are threaded to accept plugs or connectors.
94. Internal plugs are inserted into the transverse passages and/or longitudinal passages, and located as needed to produce the desired flow patterns.
95. The ends of the transverse passage and longitudinal passages are sealed with plugs, as needed.
96. Connectors are installed on the ends of one or more passages as desired.
97. An electronic assembly is mounted to the heat exchanger.

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

1-11. (canceled)

12. A method of making a heat exchanger for electronic assemblies, comprising:
a) extruding a solid heat-conductive plate having a length, a width and a thickness, with a plurality of parallel longitudinal passages enclosed in the thickness along the length of the plate;
b) drilling a plurality of parallel transverse passages drilled across at least part of the width, perpendicular to the plurality of longitudinal passages, such that each transverse passage intersects at least two longitudinal passages;
c) inserting a plurality of plugs for blocking fluid flow into the plurality of longitudinal passages and the plurality of transverse passages, the plugs being located such that fluid is constrained to flow from a fluid inlet at an end of a longitudinal passage or a transverse passage through the plurality of longitudinal passages and the plurality of transverse passages to a fluid outlet at an end of a longitudinal passage or a transverse passage.

13. The method of claim 12, further comprising sealing an open end of at least one longitudinal passage or transverse passage.

14. The method of claim 12, further comprising installing a connector at the fluid input and at the fluid output.

15. The method of claim 12, further comprising mounting an electronic assembly to the base plate.

16. The method of claim 12, further comprising cutting the base plate to a determined length.

17. The method of claim 12, in which the plate is formed with a base plate and a side wall forming an L-shaped heat exchanger.

18. The method of claim 12, in which the plate is formed with a base plate and two side walls forming a U-shaped heat exchanger.
